(19) United States
(12) Patent Application Publication
(10) Pub. No.: US 2026/0136850 A1
(43) Pub. Date: May 14, 2026

(54) OXIDATION GROWTH MODULATION

(71) Applicant: Applied Materials, Inc., Santa Clara, CA (US)

(72) Inventors: Rajesh Prasad, Lexington, MA (US); Fernando Antonio Rebolledo Uscanga, Rockport, MA (US); Shan Tang, Middleton, MA (US); Vikram M. Bhosle, North Reading, MA (US); Edwin A. Arevalo, Beverly, MA (US); Kyu-Ha Shim, Andover, MA (US); Bradley Scott Hersch, Park City, UT (US); Alexander Parker, Phoenix, AZ (US); Preston Alexander Nicol, Lehi, UT (US); Christopher Sean Olsen, Fremont, CA (US); Robin Hansen, Gloucester, MA (US); Paul William Turnbull, Inverness (GB); Zhiming Jiang, Pleasanton, CA (US); Arun Ramaswamy Srivatsa, Fremont, CA (US)

(73) Assignee: Applied Materials, Inc., Santa Clara, CA (US)

(21) Appl. No.: 18/946,121

(22) Filed: Nov. 13, 2024

(51) Int. Cl. H01L 21/02; H01L 21/265

(52) U.S. Cl. CPC H10P 14/6322; H10P 14/6309; H10P 30/204; H10P 30/21

(57) ABSTRACT

A method and a system for modulating oxide growth. A substrate is provided. A substrate implantation process is performed. Subsequent to the implantation, an oxidation of the implanted substrate is performed to modulate oxide growth.

### TECHNICAL FIELD

This disclosure relates generally to substrate processing, and in particular, to modulating oxide growth.

### BACKGROUND

Modern substrate processing includes systems that perform various applications such as manufacturing semiconductor devices, solar cell manufacturing, electronic component manufacturing, sensor fabrication, and micro-electromechanical device manufacturing. Examples of such systems include chemical vapor deposition (CVD) tools, physical vapor deposition (PVD) tools, substrate etching tools, ion implantation systems, and other systems. During manufacturing performed by such systems, it is important to control and/or modulate oxide growth to achieve desired oxide thickness, prevent creation of narrow openings between various layers of semiconductor device, etc. in final semiconductor devices. However, current oxidation techniques limit conventional systems ability to do so.

### SUMMARY

In some embodiments, the current subject matter relates to a method for modulating oxide growth, such as, for example, during substrate processing operations, according to some implementations of the current subject matter. The method may include providing a substrate, implanting the substrate, and performing, subsequent to the implanting, an oxidation of the implanted substrate to modulate oxide growth.

In some implementations, the current subject matter may include one or more of the following optional features. The substrate may be a crystalline silicon. The substrate may include a nitride layer. The nitride layer may be a silicon nitride layer.

In some implementations, the oxidation may include at least one of: a rapid thermal oxidation, a steam oxidation, and any combination thereof. The method may also, optionally, include annealing the implanted substrate prior to oxidation. The annealing may be performed using rapid thermal annealing. The annealing may be performed in a temperature range of 500 to 1200 degrees Celsius.

In some implementations, modulating of the oxide growth may include at least one of: suppressing oxide growth, enhancing oxide growth, and any combination thereof.

In some implementations, the method may also include removing one or more photoresist patterns from the substrate prior to oxidation.

In some implementations, the implant may be performed at an energy in a range of 0.2 keV to 120 keV for a beamline implantation. The implant may be performed at an energy of less than or equal to 10 kV for plasma doping implantation. The implant may be performed using at least one of the following implant species: carbon, oxygen, fluorine, germanium, helium, argon, hydrogen, nitrogen, methane, and any combinations thereof.

In some implementations, the current subject matter relates to a method for modulating oxide growth during semiconductor manufacturing. The method may include providing a crystalline silicon substrate, implanting the substrate, and performing, subsequent to the implanting, steam oxidation of the implanted substrate to modulate oxide growth.

In some implementations, the current subject matter may include one or more of the following optional features. The method may, optionally, include annealing the implanted substrate prior to oxidation using rapid thermal annealing. In some implementations, modulating of the oxide growth may include at least one of: suppressing oxide growth, enhancing oxide growth, and any combination thereof. The implant may be performed using at least one of: a beamline implantation process, a plasma doping process, and any combination thereof, and using at least one of the following implant species: carbon, oxygen, fluorine, germanium, helium, argon, hydrogen, nitrogen, methane, and any combination thereof.

In some implementations, the current subject matter relates to a method for modulating oxide growth during semiconductor manufacturing. The method may include providing a substrate having a silicon nitride layer, implanting the substrate, and performing, subsequent to the implanting, rapid thermal oxidation of the implanted substrate to modulate oxide growth by at least one of: suppressing oxide growth, enhancing oxide growth, and any combination thereof. The method may, optionally, include annealing the implanted substrate prior to oxidation using rapid thermal annealing. The implant may be performed using at least one of: a beamline implantation process, a plasma doping process, and any combination thereof, and using at least one of the following implant species: carbon, oxygen, fluorine, germanium, helium, argon, hydrogen, nitrogen, methane, and any combination thereof.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. The drawings are schematic in nature and do not represent actual dimensions or aspect ratios. In the drawings,

FIG. 1 illustrates example processes for oxide growth modulation during manufacture of semiconductor devices having different threshold voltages, according to some implementations of the current subject matter;

FIG. 2 is a flow diagram illustrating modulating oxide growth process that may be performed in accordance with phases of the processes shown in FIG. 1, according to some implementations of the current subject matter;

FIGS. 3a-d illustrate various example experimental results of modulation of oxide growth processes performed in accordance with the techniques illustrated in FIGS. 1-2, according to some implementations of the current subject matter;

FIG. 4 illustrates an example oxidation process;

FIG. 5 is a flow diagram illustrating modulating oxide growth process that may be performed to modulate oxide growth during manufacture of semiconductor devices that may include a substrate and a silicon nitride (SiN) layer positioned thereon (directly or indirectly) and/or incorporated therein, according to some implementations of the current subject matter;

FIGS. 6a-d illustrate various example experimental results of modulation of oxide growth processes performed in accordance with the techniques illustrated in FIG. 5;

FIG. 7 illustrates an example process for controlling and/or modulating oxide growth during semiconductor manufacturing, according to some implementations of the current subject matter;

FIG. 8 illustrates a schematic diagram of a processing system useful to perform processes described herein, according to some implementations of the current subject matter;

FIG. 9 illustrates an example plasma doping processing system for performing a plasma doping process, according to some implementations of the current subject matter;

FIG. 10 illustrates an example plasma treatment processing system for performing a plasma treatment process, according to some implementations of the current subject matter;

FIG. 11 illustrates an example oxidation processing system for performing an oxidation process, according to some implementations of the current subject matter; and

FIG. 12 illustrates an example plasma-enhanced chemical vapor deposition (PECVD) system that may be used to deposit thin films from a gas state (e.g., vapor) to a solid state on a substrate, according to some embodiments of the current subject matter.

### DETAILED DESCRIPTION

To address these and potentially other deficiencies of currently available solutions, one or more implementations of the current subject matter relate to methods, systems, articles of manufacture, and the like that can, among other possible advantages, provide an ability to perform substrate processing, and in particular, to perform modulation (e.g., enhancement and/or suppression) of oxide growth.

In some implementations, the current subject matter relates to modulation of oxide growth process, and in particular, performing substrate implantation processes prior to oxidation operations, which may be configured to control or modulate oxide growth, e.g., oxide growth enhancement and/or oxide growth suppression.

In semiconductor manufacturing, modulation and/or controlling of oxide growth modulation may be important for producing high-quality gate oxides, passivation layers, and/or any other electronics components. Thermal oxidation, steam oxidation, ion implantation, plasma doping, rapid thermal annealing, and/or any other techniques may be used for controlling oxide growth.

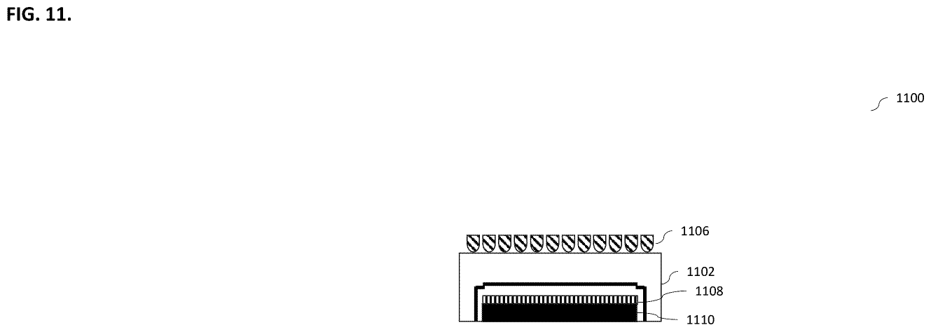

Thermal oxidation (which may include and/or be referenced as rapid thermal oxidation (RTO)), as for example, is shown in FIG. 11, may refer to a growth of thin oxide layers on silicon wafers by rapidly heating them in an oxidizing atmosphere. Some examples of such atmosphere include oxygen oxidizing atmosphere, which results in high-quality oxides, and nitrous oxide and/or nitric oxide, which incorporate nitrogen into oxide, thereby improving various electrical properties, reliability, etc. of resulting semiconductor devices. The oxide growth typically occurs at temperatures between 950° C. and 1200° C. during short periods of times (e.g., seconds to minutes). Further, these processes may occur during a low system pressure (which can enhance growth rates) and/or atmospheric pressure. Annealing in nitric oxide and/or other ambients may be performed subsequent to improve electrical characteristics of oxides.

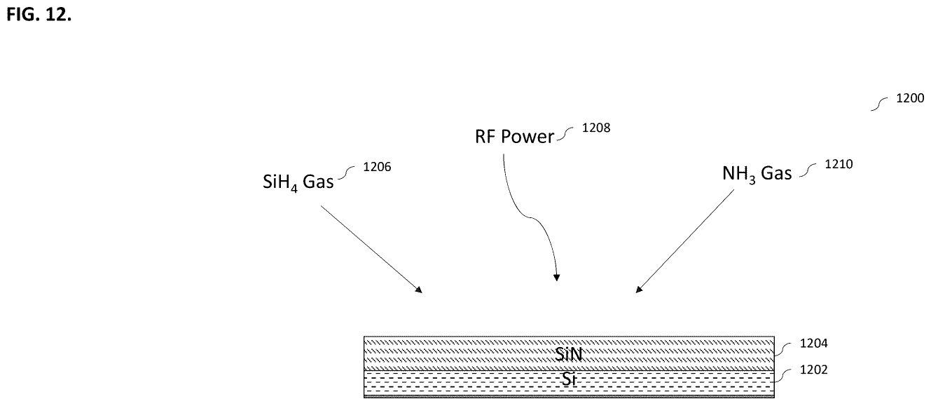

Plasma-enhanced chemical vapor deposition refers to a process that may be used to deposit thin films from a gas state (e.g., vapor) to a solid state on a substrate. This process is used to create high-quality films at relatively low temperatures. PECVD (as shown in FIG. 12) involves generation of plasma using radio frequency (RF) and/or direct current (DC) discharge between two electrodes. Plasma can provide the energy needed for chemical reactions to occur, which, in turn, allows deposition of thin films on the substrate. PECVD can be performed at lower temperatures (e.g., room temperature to 350° C.).

In some implementations, the current subject matter's oxide growth modulation process may be conducted in one or more phases and/or stages (terms used interchangeably herewith). These may include an implantation phase and an oxidation phase performed subsequent to the implantation phase. This may allow for modulation or control of oxide growth, e.g., suppression and/or enhancement.

In general, oxide growth modulation may include a process control of formation and/or characteristics (e.g., thickness) of one or more oxide layers on a substrate. Oxide growth modulation may be achieved through various techniques that may include variation of process parameters associated with one or more phases of the oxide growth modulation. For example, adjusting temperature during the oxidation phase may be configured to influence growth rate and/pr quality of the oxide layer. Use of different gases (e.g., oxygen, nitrous oxide, etc.) may modify chemical environment and/or properties of the oxide. Further, pressure changing may also affect oxidation kinetics and/or resulting film characteristics. Last, but not least, oxide growth modulation may be achieved by controlling duration of oxidation process in order to achieve desired thickness(es) and/or property(ies) of the oxide layer.

In some implementations, the current subject matter relates to a process for controlling and/or modulating oxide growth during semiconductor manufacturing. The process may be used to manufacture one or more devices, e.g., a semiconductor device that may include a plurality of layers, structures, devices, features, etc. The devices may be at various stages of fabrication, including, but not limited to, memory devices, logic devices, CMOS devices, etc. The layers, structures, devices, features, etc. may be formed on and/or within an underlying substrate and/or may be patterned in the device being manufactured. The layers, structures, devices, features, etc. may form any type of layer and/or layers, which may, for example, but not limited to nitride layer(s), insulator layer(s), metal layer(s), semiconductor layer(s) and/or any other type of layers and/or any combination thereof.

The substrate, which may be used during the current subject matter's oxide modulation process, may be a crystalline silicon (cSi), a substrate that may include a nitride layer (e.g., a silicon nitride layer) positioned thereon (directly or indirectly) and/or incorporated therein, and/or any other type of substrate. Crystalline silicon can be used during production of semiconductor devices, solar cells, etc. due to its excellent electronic properties. Crystalline silicon can include monocrystalline silicon and/or polycrystalline silicon. Monocrystalline silicon can be manufactured from a single continuous crystal structure. It provides high efficiency and performance and can be used in high-performance solar cells, advanced semiconductor devices, etc. Polycrystalline silicon includes multiple small silicon crystals and/or grains and can be used in solar panels, various semiconductor devices, and/or for any other applications.

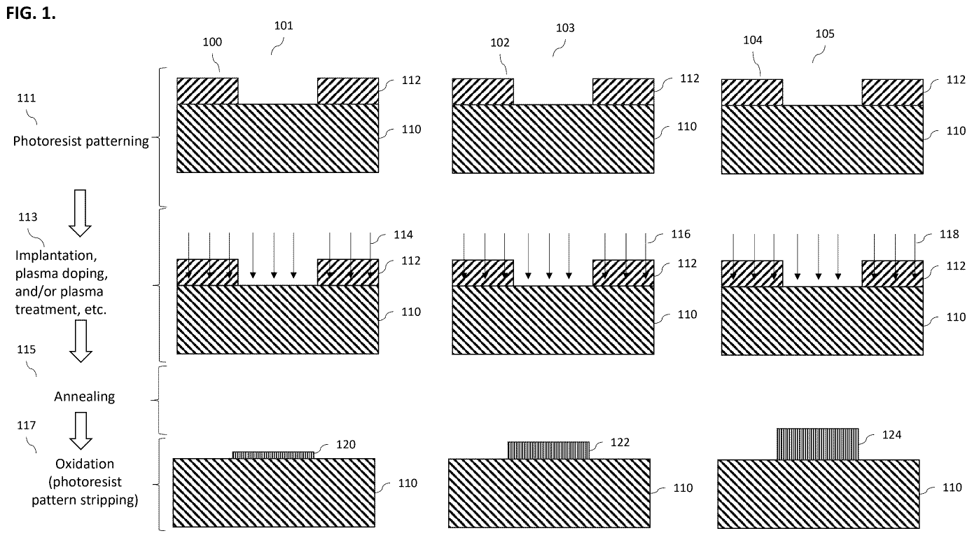

In some example, implementations, one or more photoresist patterns may be formed on the substrate (as, for example, is shown in FIG. 1). The photoresist patterning may, for example, be performed in accordance with a specific threshold voltage that is desired to be achieved by the semiconductor device. Once photoresist patterns are achieved, implantation phase may be performed.

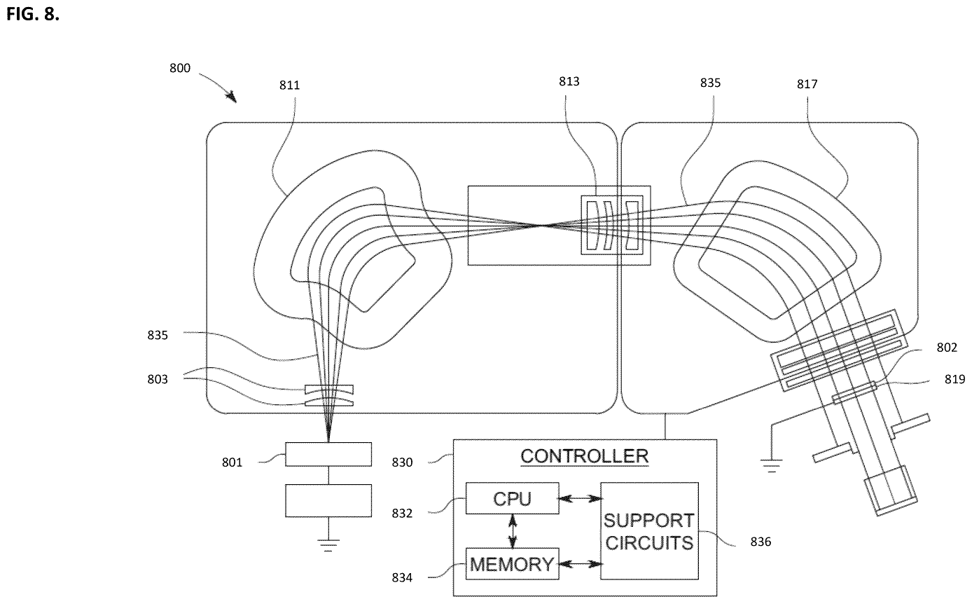

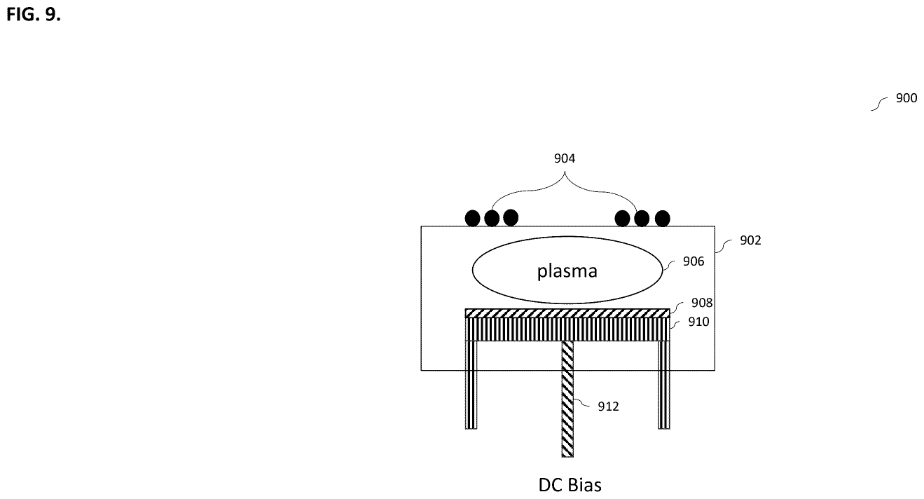

In some cases, implantation may be limited to open regions that may be formed as a result of the patterning. Alternatively, or in addition, implantation may be performed in any and/or all locations on the substrate. The implantation phase may be configured to implant one or more implant species into materials on the substrate. By way of a non-limiting example, the implant species may be ions that may have an energy in the range 0.2 keV to 120 keV. Example implant species may include, but are not limited to, at least one of the following: carbon, nitrogen, silicon, germanium, helium, neon, argon, and/or any other species, and/or any combination of species. The energy and/or angle of incidence at which the implant species may be applied by the implantation system (e.g., system 800 shown in FIG. 8, system 900 shown in FIG. 9, etc.) may be selected so that the implant species may be incorporated in one or more layers of the semiconductor device, not incorporated, and/or incorporated to a lesser extent in other layers. By way of a non-limiting example, implant tilt angles can range from 0 to 10 degrees, and a wafer's twist angle can start at 0 degrees, where the wafer can, subsequently, be rotated 90 degrees, 180 degrees, and/or any other number of degrees. The dose of the implant species may also be selected so that an implant concentration of 1E15/cm³ up to 5E16/cm³ may be generated in the substrate using a beamline approach (e.g., using system 800 shown in FIG. 8) and less than or equal to 5E16/cm³ using plasma doping approach (e.g., using system 900 shown in FIG. 9).

In some optional implementations, an optional anneal phase may be performed subsequent to the implantation phase. The anneal phase may be performed using any suitable apparatus, which may include, for example, a furnace anneal, an anneal on a platen, a rapid thermal anneal, an anneal using radiation, etc. The anneal may, for example, be conducted at temperatures ranging from 125° C. to 1100° C., for periods of one millisecond up to several minutes. Alternatively, or in addition, no anneal may be performed.

Post the anneal phase, the current subject matter may be configured to perform oxidation phase. In some implementations, an optional removal or stripping of photoresist layers formed during the initial photoresist patterning may be performed prior to the oxidation phase.

The oxidation phase may include a thermal oxidation (e.g., rapid thermal oxidation (RTO)), a steam oxidation, and/or any other type of oxidation, and/or any combination thereof. Thermal oxidation may be used to grow thin oxide layers on silicon wafers by rapidly heating them in an oxidizing atmosphere. Control and/or modulation of the thermal oxidation's oxide growth may involve adjustment of one or more parameters associated with the oxidation phase to control thickness and/or quality of the oxide layer being formed. The parameters may include a type of oxidizing atmosphere, temperature, time, pressure, and/or any other parameters. The oxidizing atmosphere may include oxygen (O₂) based atmosphere (e.g., which may be used for dry oxidation), nitrous oxide (N₂O) and/or nitric oxide (NO) based atmosphere (e.g., which may be used to incorporate nitrogen into the oxide). A typical temperature associated with the thermal oxidation's ranges from 950° C. and 1200° C., where oxidation is performed during a short period of time (e.g., seconds, minutes, etc.) so that a desired oxide thickness may be achieved. The pressure may include a low pressure (e.g., to enhance growth rates in certain ambients, such as, N₂O), an atmospheric pressure (e.g., a standard pressure), and/or any other pressure.

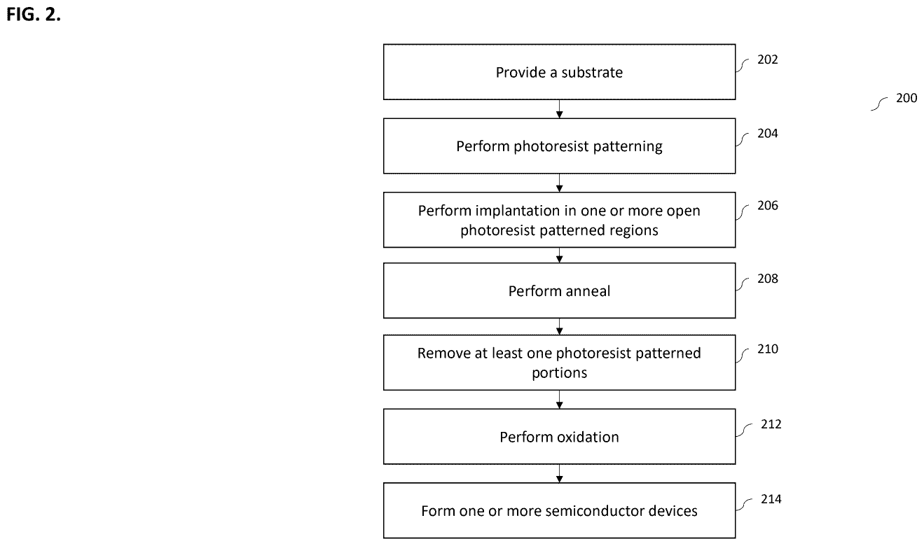

FIGS. 1-2 illustrate an example processes for modulating oxide growth, according to some implementations of the current subject matter. In particular, FIG. 1 illustrates processes 101, 103, and 105 for oxide growth modulation during manufacture of semiconductor devices having different threshold voltages (Vₜ). FIG. 2 is a flow diagram illustrating modulating oxide growth process 200 that may be performed in accordance with phases of the processes 101-105 shown in FIG. 1, according to some implementations of the current subject matter.

In particular, the process 101 illustrates oxide growth modulation for a semiconductor device 100 having a low threshold voltage. The process 101 may result in the semiconductor device 100 having a thin oxide layer thickness. The process 103 illustrates oxide growth modulation for a semiconductor device 102 having a standard threshold voltage. The process 103 may result in the semiconductor device having a standard oxide layer thickness. The process 105 illustrates oxide growth modulation for a semiconductor device 104 having a high threshold voltage. The process 105 may result in the semiconductor device having a thick oxide layer thickness. By way of a non-limiting example, experimental oxide thicknesses may vary from approximately 5 Angstrom (A) to 100 A. As can be understood, any other oxide thicknesses may be generated. The processes 101-105 may be performed using system 800 (e.g., a beamline system) shown in FIG. 8, system 900 (e.g., plasma doping system, plasma treatment system, etc.) shown in FIG. 9, and/or any other suitable system.

Each of the processes 101-105 may include one or more phases, which may be an optional photoresist patterning phase 111, an implantation phase 113, an annealing phase 115, and an oxidation phase 117, wherein the oxidation phase 117 may also include and/or be preceded by removal of the photoresist layer(s) that may be formed during the patterning phase 111. The oxidation phase 117 may follow the implantation, plasma doping, and/or plasma treatment, etc. phase 113 (and optionally, the annealing phase 115), which may allow the current subject matter to modulate and/or control oxide growth. Oxide growth modulation may be uniform, e.g., suppression of oxide growth or enhancement of oxide growth in the entire semiconductor device. Alternatively, or in addition, oxide growth modulation may be selective, e.g., suppression of oxide growth in one area while enhancing oxide growth in another area of the semiconductor device. As can be understood, oxide growth modulation may be performed in any desired way.

Each of the processes may be based on a substrate 110 (as may be provided at 202 as shown in FIG. 2), on which one or more photoresist layers 112 may be formed during the patterning phase 111, at 204. The substrate may be a crystalline silicon (cSi) substrate, a substrate that may include a nitride layer (e.g., a silicon nitride layer) positioned thereon (directly or indirectly) and/or incorporated therein, and/or any other type of substrate. The photoresist patterning may be performed using any suitable techniques.

Once photoresist patterning is completed, the ion implantation phase 113 may be initiated, at 206. Different implantation techniques may be used for implanting implant species or chemistries 114 onto the substrate 110. Selection of such implantation techniques and/or implant species may depend on, for example, specific threshold voltage that the final semiconductor device should have. For example, ion implantation may be performed using a beamline tool, a plasma implantation tool, and/or any other tools. Some non-limiting implantation systems may include, for example, VARIAN VIISta 900XP system, VIISta HCP system, VIISta Trident Crion system, VIISta PLAD system, etc. (as available from Applied Materials, Santa Clara, CA, USA). The implantation systems may have various capabilities, including performance of cold temperature implants, room temperature implants, hot temperature implants, etc. One or more parameters of the implantation process executed by the implantation system may be specifically configured for a particular end result. The parameters may include, but are not limited, to temperature, energy, pressure, time, dose, and/or any other parameters, and/or any combinations thereof. For instance, some implant species implanted by the implantation systems may include, but are not limited to, carbon, oxygen, fluorine, germanium, helium, argon, hydrogen, nitrogen, methane, etc. The applied energy may be 0.2 keV to 120 keV (and in particular, 10 keV for beamline and 10 kV for plasma doping) and/or dose of 1e15 to 1e17 ions/cm². In some non-limiting implementations, implantation may be performed at a temperature of −100° to 700° Celsius for a beamline approach (e.g., using system 800 shown in FIG. 8), and at a temperature of 25° to 500° Celsius for plasma doping (e.g., using system 900 shown in FIG. 9).

In some implementations, implantation phase 113 may be conducted as an angled implantation, where the angle of the trajectories of implant species with respect to a perpendicular to a main plane of the substrate (e.g., X-Y plane according to the Cartesian coordinate system shown) may be between 0 degrees and 80 degrees. When an angled implantation is to be performed, the substrate may be rotated in the X-Y plane using a suitable rotation sequence (e.g., rotation angle of 180 degrees, rotation angle between 0 and 180 degrees, and/or any other rotation angle). The rotation sequence may depend upon the feature and/or implant species being implanted. For example, for a line structure implant the angled implantation may be performed at a rotation angle of 0 degrees and/or 180 degrees. If the implanted feature is a circle, e.g., a via, then implantation may be performed at various rotation angles, e.g., 0 degrees, 90 degrees, 180 degrees, 270 degrees, etc. Any number of rotations may be performed and/or decreased/increased from the initial number of rotations to as many as is needed to uniformly implant the feature.

Referring back to FIG. 1, the process 101 may include implanting carbon implant species or chemistries 114 and/or any other implant species/chemistries. The process 101 may be performed using any desired temperature, e.g., cold, room, and/or hot temperature, where in the case of the latter, implantation may use a high-temperature electrostatic chuck (e.g., Thermion™). The process 103 may be performed without any implant. The process 105 may include implanting oxygen implant species (and/or any other species) 118 and may be performed using any desired temperature, e.g., cold, room, and/or hot temperature (e.g., using Thermion™). In some example, implementations, implantations may involve plasma treatment and/or plasma densification treatment, which may include infusing nitrogen into silicon oxide (dielectric) using a low-energy, pulsed plasma. This may create a high nitrogen concentration at the oxynitride/poly interface and a low concentration at the silicon/oxynitride interface of the gate stack. This, in turn, preserve high channel mobility and improve the electrical characteristics of the gate insulator. Plasma treatment may be useful for advanced logic and memory applications, whereby performance of oxynitride gates is enhanced by reducing gate leakage and improving resistance against dopant diffusion.

Upon completion of implantation, the processes 101-105 may include an optional annealing phase 115, at 208. Annealing may be performed using a rapid thermal annealing (RTA) or rapid thermal processing (RTP) technique. RTA may include quickly heating silicon wafers to high temperatures, typically, over 1000° C. during very short time period (e.g., seconds, or less) and then cooling them down slowly to prevent thermal shock. In some example implementations, the annealing process may be performed with a thermal anneal process chamber using various process species/chemistries for optimized film treatment, which may, for instance, include, but are not limited to N₂, NH₃, H₂, O₂, and/or any other elements. The anneal process may be performed at temperatures between in a range of 350° C.-1200° C. and up to atmospheric pressure.

The processes 101-105 may conclude with an optional removal of the photoresist, at 210, and the oxidation phase 117, at 212. For example, at the conclusion of the process 101, the resulting semiconductor device may include a thin oxide layer 120 disposed on the substrate 110. This will enable the semiconductor device (e.g., complementary metal oxide semiconductor (CMOS)) to have a lower threshold voltage (Vₜ). The process 103 may result in the semiconductor device having a nominal or standard oxide layer 122 disposed on the substrate 110, thereby having a standard threshold voltage (Vₜ). The process 105 may result in the thicker oxide layer 124 semiconductor device, which may be characterized by a high threshold voltage (Vₜ).

The oxidation process may be performed by a thermal oxidation process chamber using various process chemistries to optimize oxide growth and selectivity. For example, process species/chemistries may include, but are not limited to, O₂, H₂, N₂O, and/or any other species/chemistries. The oxidation process may be performed at temperatures in a range of 350° C.-1200° C. and up to atmospheric pressure. Alternatively, or in addition, the oxidation process may be performed at pressures below 550 Torr and utilize a partial pressure in a range of 100 to 250 Torr of H₂O steam for oxide growth. Upon completion of the oxidation phase and/or any other post processing operations, the semiconductor device may be formed, at 214.

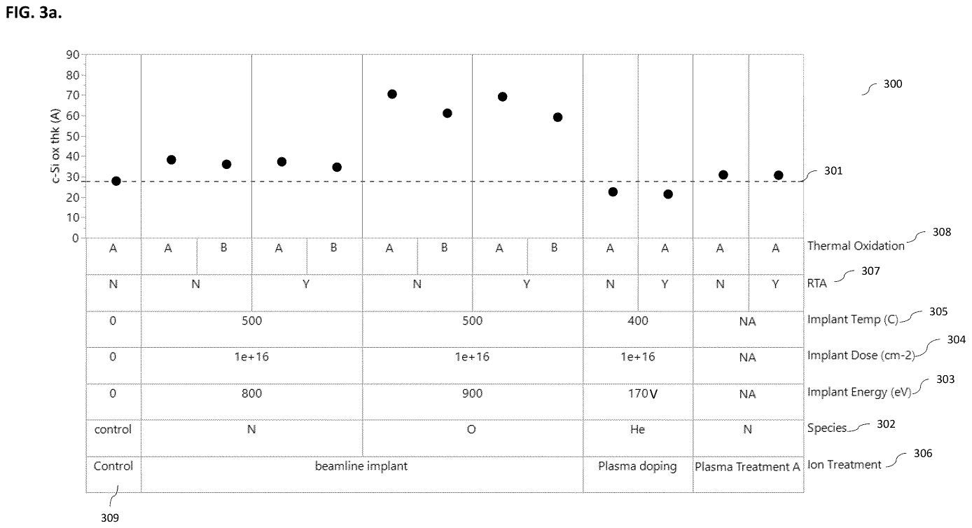

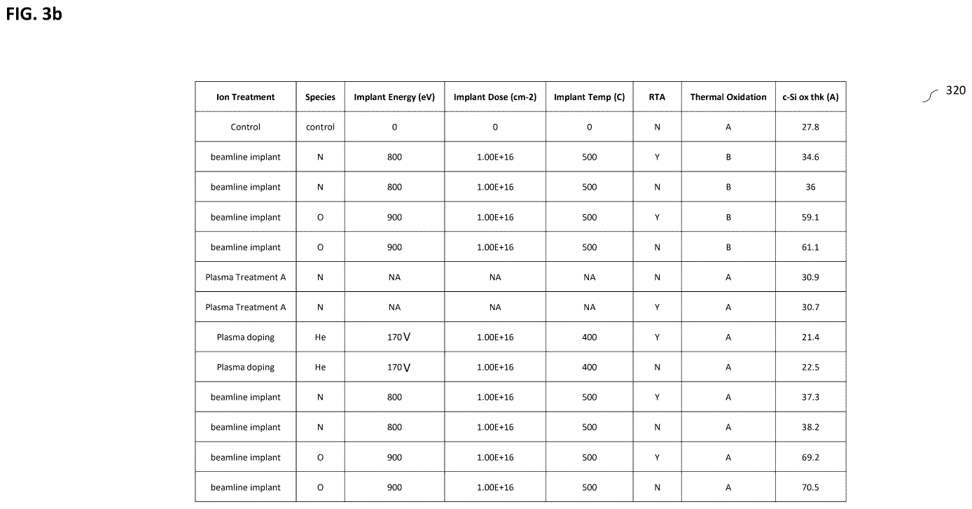

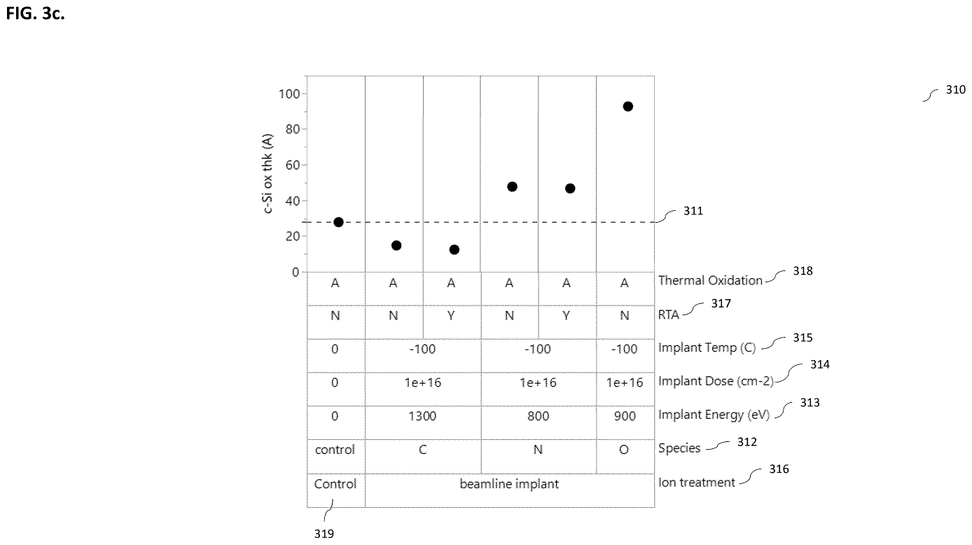

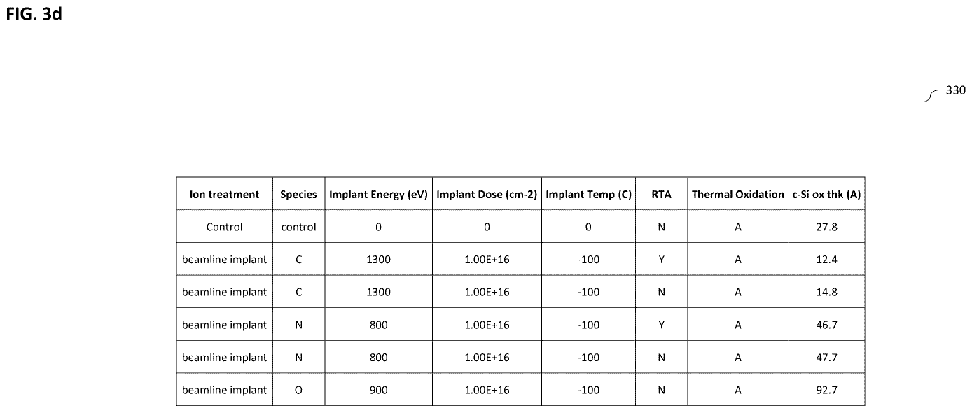

FIGS. 3a-d illustrate various example experimental results of modulation of oxide growth processes performed in accordance with the techniques illustrated in FIGS. 1-2.

FIG. 3a is an example plot 300 and FIG. 3b illustrates a corresponding table 320 showing oxide growth modulation based on a crystalline silicon substrate in view of use of various implant species and parameters. In particular, the plot 300 illustrates oxide thickness data points (in angstrom (A)) when different implant species are used under different conditions defined by parameters 302-308. The data points are compared to the control data point 309 as represented by the control line 301 (at approximately 30 A) when no implant is present.

The implant species 302 used during the experiments included nitrogen, oxygen, and helium, where different implantation techniques were used (as defined by the ion treatment parameter 306), which included a beamline implantation process, a plasma doping process, and a plasma treatment process (e.g., plasma densification treatment), each of which may be optimized using one or more parameters, e.g., time, temperature, chemical parameters, pressure, plasma energy, etc. (e.g., chemical species of N₂, NH₃, He, and Ar; temperature up to 450 C; pressure between 10 mTorr and 200 mTorr; and plasma energy up to 2200 W). Energy parameter 303 varied for each implant specie being used, e.g., for nitrogen, the energy of 800 eV was used for beamline implantation (ion treatment parameter 306); for oxygen—900 eV was used for beamline implantation; for helium—170 V was used for plasma doping; etc. Dose parameter 304 likewise varied for each implant specie, e.g., for nitrogen, the dose of 1e16 ions/cm²; for oxygen, the dose of 1e16 ions/cm²; etc. The implant temperature parameter 305 varied for each implant specie, e.g., for nitrogen and oxygen, the temperature used was 500° Celsius for beamline implantations; for helium—400° Celsius for plasma doping. Annealing parameter 307 indicates whether or not annealing was performed. Lastly, the oxidation parameter 308 indicated a type of oxidation that was performed during experiments (e.g., steam oxidation (shown as “A” in FIGS. 3a-b), or rapid thermal oxidation (shown as “B” in FIGS. 3a-b), etc.). As shown in FIGS. 3a-b, steam oxidation was performed for plasma doping and plasma treatment processes involving He and N species. Each of the steam oxidation and RTO was performed for beamline implantation process for N and O species. The resulting oxide thickness ranged from approximately 21.4 A to approximately 70.5 A.

As shown in FIG. 3a, for nitrogen implant species, minor oxide growth enhancement was observed when beamline implantation (as shown by parameter 306) was used and negligible effect on oxide growth was observed when plasma treatment was used, i.e., most oxide thicknesses was centered around the control line 301. Minor oxide growth suppression was observed when plasma doping was used for helium implant species. Substantial oxide growth enhancements were observed for oxygen implant species when beamline implantation was used.

FIG. 3c is another example plot 310 and FIG. 3d illustrates a corresponding table 330 showing oxide growth modulation based on a crystalline silicon substrate in view of a use of various implant species and parameters. In particular, similar to the plot 300 shown in FIG. 3a, the plot 310 illustrates oxide thickness data points (in angstrom (A)) when different implant species are used under different conditions defined by parameters 312-318. The data points are compared to the control data point 319 as represented by the control line 311 (at approximately 30 A) when no implant is present.

The implant species 312 used during the experiments included carbon, nitrogen, and oxygen. Beamline implantation process (as indicated by parameter 316) was used during the experiment. Energy parameter 313 varied for each implant specie being used and ranged from 800-1300 eV. Dose parameter 314 was set at 1e16 ions/cm² for each experiment. The implant temperature parameter 315 was set to −100° Celsius. Parameter 317 indicated whether thermal annealing was used. The oxidation parameter 318 indicated a type of oxidation that was performed during experiments (e.g., steam oxidation (shown as “A” in FIGS. 3c-d). As shown in FIG. 3c, steam oxidation was performed for beamline implantation process for C, N and O species.

As shown in FIG. 3c, whether or not annealing was performed had some effect on oxide growth (enhancement and/or suppression). An oxide growth suppression occurred for carbon implant species irrespective of whether annealing was performed. An oxide growth enhancement was observed for nitrogen implant species irrespective of whether annealing was performed. Substantial oxide growth enhancement was observed for oxygen implant species when annealing was not performed. The resulting oxide thickness ranged from approximately 12.4 A to approximately 92.7 A.

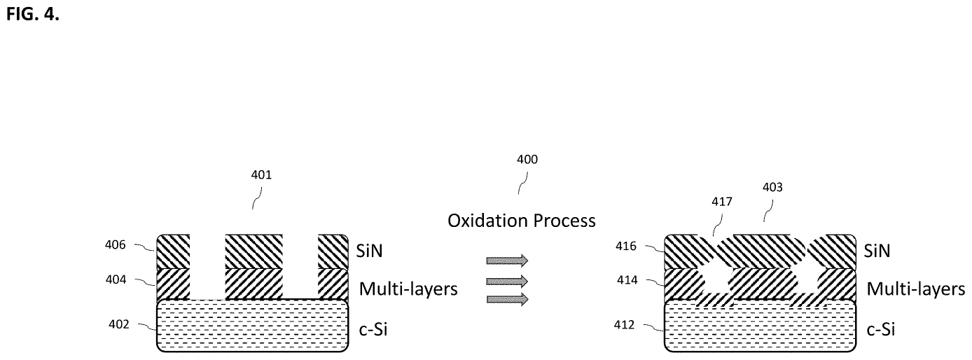

FIG. 4 illustrates an example oxidation process 400. The process 400 may be configured to modulate oxide growth on the silicon-nitride (SiN) layer that may be positioned on a substrate (directly or indirectly) and/or incorporated therein. In particular, the process 400 may be used to maintain critical dimension opening from SiN layer to the silicon (Si) substrate. The SiN layer may oxidize faster than one or more of the underlying layers, also referred to as multi-layers, which may result in an undesired narrower opening in the SiN layer. The narrower opening may cause subsequent restriction of contact material with the substrate and/or lower doping effect by ion implantation.

As shown in FIG. 4, the oxidation process 400 may be initiated with a device 401 having a substrate, e.g., cSi substrate, 402, one or more multi-layers 404 positioned on the substrate 404, and a SiN layer 406 positioned on the layers 404. As can be understood, any arrangement of layers 402-406 may be possible, e.g., the SiN layer 406 may be positioned (directly or indirectly) on the substrate 402 and/or be incorporated therein.

Oxidation of the device 401 may result in device 403 that may include substrate 412 (similar to or the same as substrate 402), multi-layers 414, and SiN layer 416. The multi-layers 414 are produced as a result of oxidation process 400 applied to the multi-layers 404. The SiN layer 416 is produced as a result of oxidation process 400 applied to the SiN layer 406. As shown in FIG. 4, the SiN layer 416 has grown more than the multi-layers 414 as a result of oxidation process 400, thereby creating narrower opening(s) 417.

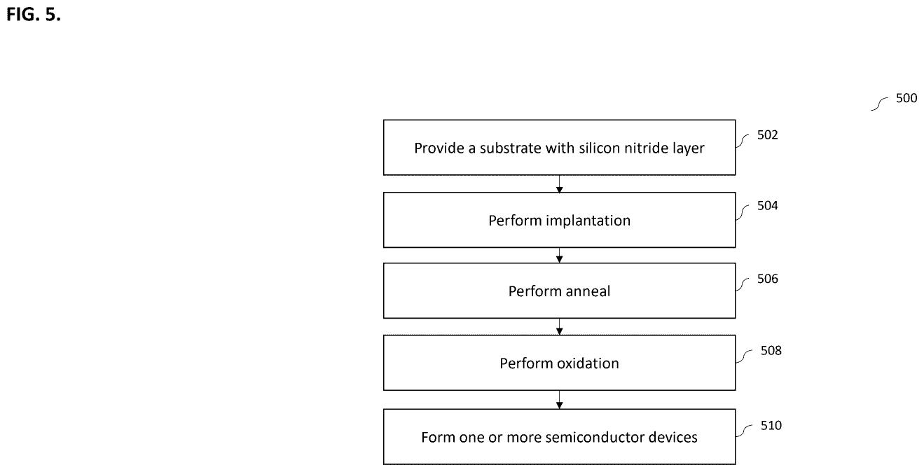

FIG. 5 is a flow diagram illustrating modulating oxide growth process 500 that may be performed to modulate oxide growth during manufacture of semiconductor devices that may include a substrate and a silicon nitride (SiN) layer positioned thereon (directly or indirectly) and/or incorporated therein, according to some implementations of the current subject matter. One or more of the process operations of the process 500 may be similar to those illustrated and discussed herein in connection with FIGS. 1-2.

Similar to FIGS. 1-2, the process 500 may include one or more phases, which may be an optional photoresist patterning phase, an implantation phase (at 504), an optional annealing phase (at 506), an oxidation phase (at 508), and semiconductor formation phase (at 510). The oxidation phase may follow the implantation phase (and optionally, the annealing phase), which may allow the current subject matter to modulate and/or control oxide growth of the SiN layer. Oxide growth modulation may be uniform, e.g., suppression of oxide growth or enhancement of oxide growth in the entire semiconductor device. Alternatively, or in addition, oxide growth modulation may be selective, e.g., suppression of oxide growth in one area while enhancing oxide growth in another area of the semiconductor device. As can be understood, oxide growth modulation may be performed in any desired way.

Each of the processes may be based on a substrate that may include a SiN layer (e.g., substrate 402 and SiN layer 406, as shown in FIG. 4, and as may be provided at 502, as shown in FIG. 5). The substrate may be a crystalline silicon (cSi) substrate, a substrate that may include a nitride layer (e.g., a silicon nitride (SiN) layer) positioned thereon (directly or indirectly) and/or incorporated therein, and/or any other type of substrate.

The implantation phase may be performed, at 504. The implantation phase of the process 500 may be similar to the implantation phase 113 of the processes shown in FIGS. 1-2. As discussed herein, different implantation techniques may be used for implanting one or more implant species, where selection of implantation techniques and/or implant species may depend on, for example, specific threshold voltage that the final semiconductor device should have. For example, ion implantation may be performed using a beamline tool, a plasma doping implantation tool, and/or any other tools. The implantation process may be defined by one or more implantation parameters, e.g., temperature, energy, pressure, time, dose, and/or any other parameters, and/or any combinations thereof. For example, temperature may be cold, room, and/or hot temperature (e.g., −100° Celsius for cold, 23° Celsius for room, and 500° Celsius for hot). Implant species may include, but are not limited to, carbon, oxygen, fluorine, germanium, helium, argon, hydrogen, nitrogen, methane, etc. The applied energy may range from 0.2 keV to 120 keV (and in particular, 10 keV for beamline and 10 kV for plasma doping) and/or dose of 1e15 to 1e 17 ions/cm².

Upon completion of implantation, the process 500 may include an optional annealing phase, at 506, which may include a rapid thermal annealing (RTA) or rapid thermal processing (RTP) technique. The oxidation phase may follow the annealing phase, at 508. As discussed herein, the oxidation process may include various thermal oxidation methods/techniques, such as, for example, but not limited to, rapid thermal oxidation and/or steam oxidation. Oxidation may be performed by a thermal oxidation process chamber using various process chemistries to optimize oxide growth and selectivity. Upon completion of the oxidation phase and/or any other post processing operations, the semiconductor device may be formed, at 510.

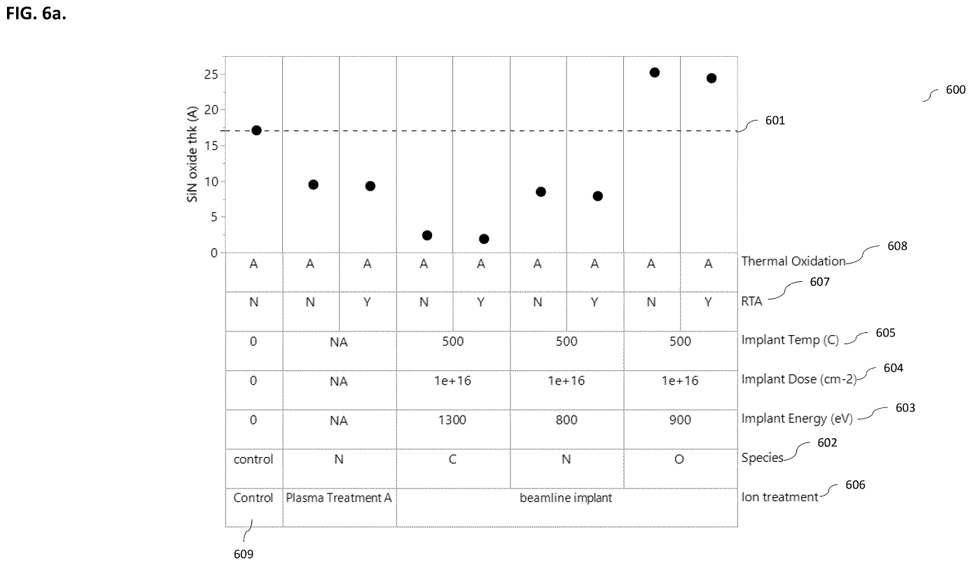

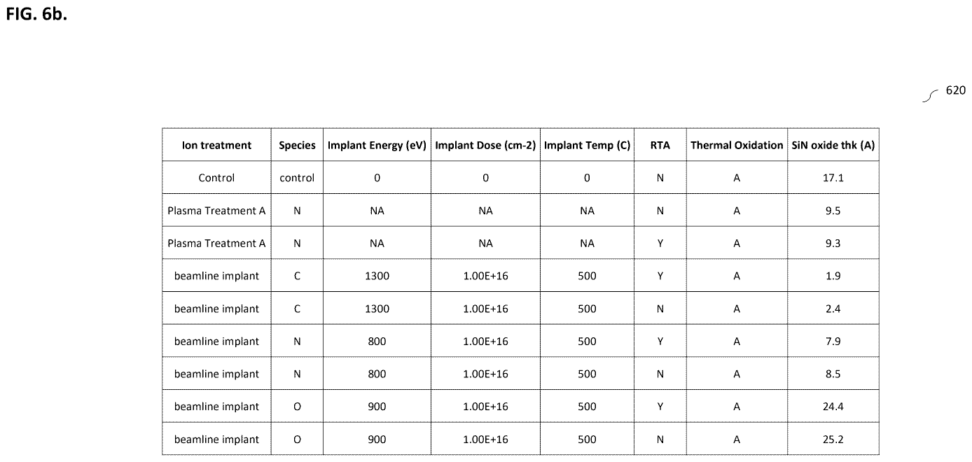

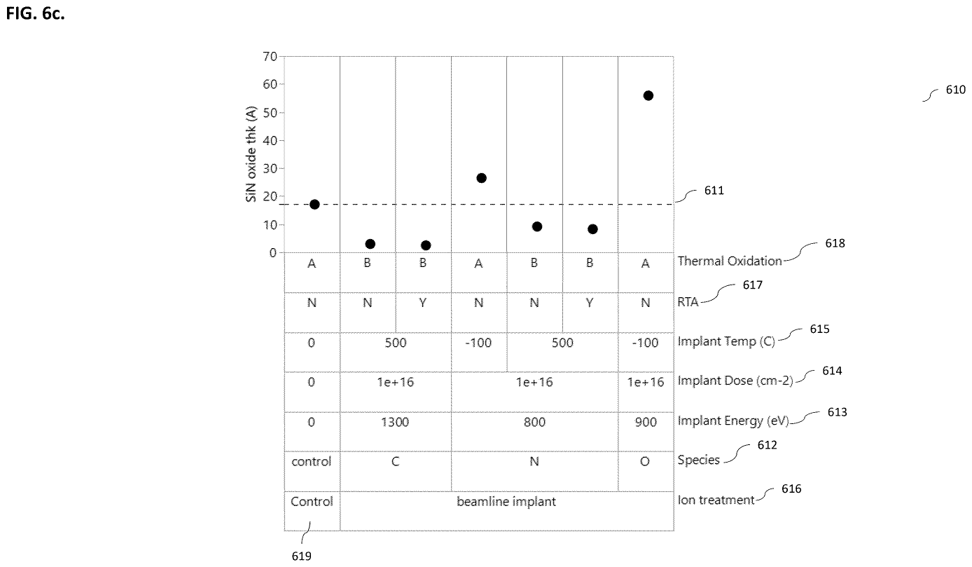

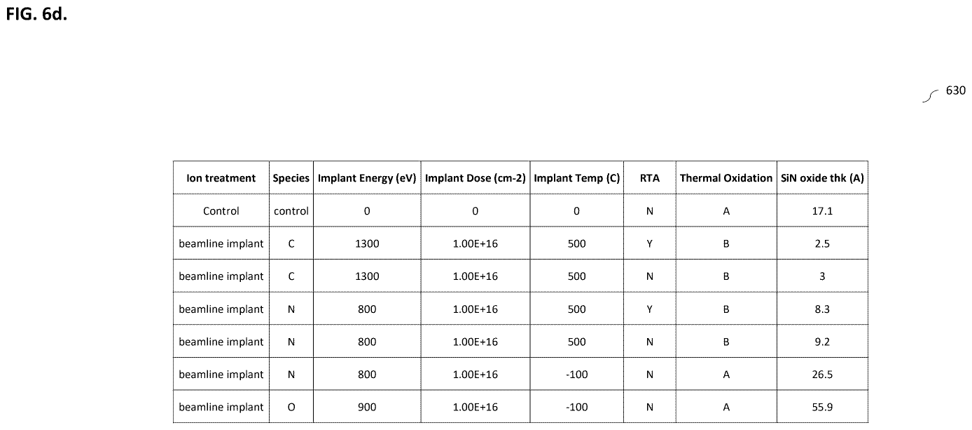

FIGS. 6a-d illustrate various example experimental results of modulation of oxide growth processes performed in accordance with the techniques illustrated in FIG. 5.

FIG. 6a is an example plot 600 and FIG. 6b illustrates a corresponding table 620 showing oxide growth modulation based on a substrate having a SiN layer disposed thereon (directly or indirectly) and/or incorporated therein, in view of use of various implant species and parameters. In particular, the plot 600 illustrates oxide thickness data points (in angstrom (A)) when different implant species are used under different conditions defined by parameters 602-608. The data points are compared to the control data point 609 as represented by the control line 601 (at approximately 30 A) when no implant is present.

The implant species 602 used during the experiments included carbon, nitrogen, and oxygen, where different implantation techniques were used (as defined by the ion treatment parameter 606), which included a plasma treatment process (e.g., plasma densification treatment) and a beamline implantation process, each of which may be optimized using one or more parameters, e.g., time, temperature, chemical parameters, pressure, plasma energy, etc., as discussed above with regard to FIGS. 3a-d. Energy parameter 603 (for beamline implantation) varied for specific implant specie being used, e.g., for carbon, the energy of 1300 eV was used, for nitrogen, the energy of 800 eV was used; for oxygen—900 eV was used. Dose parameter 604 (for beamline implantation) was set for each implant specie at 1e16 ions/cm². The implant temperature parameter 605 (for beamline implantation) was likewise for each implant specie at 500° Celsius. Annealing parameter 607 indicated whether or not annealing was performed. Lastly, the oxidation parameter 608 indicated a type of oxidation that was performed during experiments (e.g., steam oxidation (shown as “A” in FIGS. 6a-b)).

As shown in FIG. 6a, substantial oxide growth enhancement was observed for oxygen implant species irrespective of whether annealing was performed. For nitrogen implant species, when plasma treatment process was used, relatively substantial oxide growth suppression occurred irrespective of whether annealing was performed, as shown by data points below the control line 601. Similar oxide growth suppression was obtained when beamline implantation process was used for nitrogen implant species. Substantial oxide growth suppression was observed for carbon implant species when beamline implantation was used (e.g., from 17.1 A (control) to 1.9 A (1E16)), and again, irrespective of whether annealing was performed. The resulting oxide thickness ranged from approximately 1.9 A to approximately 25.2 A.

FIG. 6c is another example plot 610 and FIG. 6d illustrates a corresponding table showing oxide growth modulation based on a substrate that may include a silicon nitride layer thereon (either directly or indirectly) and/or incorporate therein. Similar to the plot 600 shown in FIG. 6a (and plot 310 shown in FIG. 3c), the plot 610 illustrates oxide thickness data points when different implant species are used under different conditions defined by parameters 612-618. The data points are compared to the control data point 619 as represented by the control line 611 when no implant is present.

The implant species 612 used during the experiments included carbon, nitrogen, and oxygen. Beamline implantation process was used, as defined by the ion treatment parameter 616. Energy parameter 613 varied for each implant specie being used and ranged from 800-1300 eV. Dose parameter 614 was set at 1e16 ions/cm² for each experiment. The implant temperature parameter 615 was set to either −100° Celsius or 500° Celsius based on whether rapid thermal anneal (as represented by the annealing parameter 617) was performed. The oxidation parameter 618 indicated a type of oxidation that was performed during experiments (e.g., steam oxidation (shown as “A” in FIGS. 6c-d) or rapid thermal oxidation (shown as “B” in FIGS. 6c-d)). As shown in FIG. 6 c, RTO was performed for beamline implantation process for C species. Steam oxidation and RTO was performed for beamline implantation process for N species. Steam oxidation was performed for beamline implantation process for O species.

As shown in FIG. 6c, substantial oxide growth enhancement occurred with oxygen implant species at −100° Celsius temperature. Oxide growth suppression occurred with nitrogen and carbon implant species at implant temperatures of 500° Celsius irrespective of whether annealing was performed. The highest oxide growth suppression was observed with carbon implant species from 17.1 A (control) to 2.5 A. Oxide growth enhancement was observed for nitrogen implant species at −100° Celsius implant temperature when no annealing was performed. The resulting oxide thickness ranged from approximately 2.5 A to approximately 55.9 A.

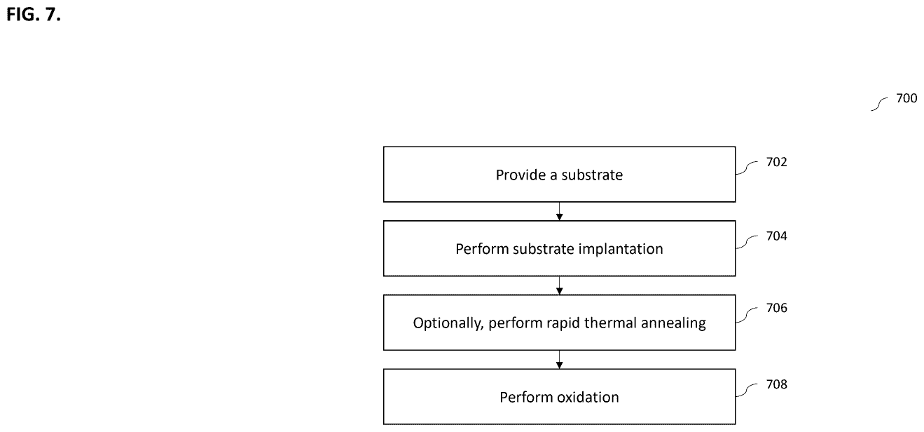

FIG. 7 illustrates an example process 700 for controlling and/or modulating oxide growth during semiconductor manufacturing, according to some implementations of the current subject matter. The process 700 may be performed by the system 800 shown in FIG. 8 and may be optimized using one or more parameters, such as, for example, implant species, implant temperature, applied energy, dose, whether or not annealing is performed, type of oxidation performed, and/or any other parameters, and/or any combination thereof. The process 700 may be performed in accordance with one or more phases or stages, as discussed herein in connection with FIGS. 1-6d.

At 702, a substrate may be provided (e.g., positioned on a platen within system 800). The substrate may be a crystalline silicon substrate. Alternatively, or in addition, the substrate may include a nitride layer thereon (either directly or in directly) and/or incorporated therein. The nitride layer may be a silicon nitride layer.

At 704, implantation may be performed. Implantations may be performed at an energy in a range of 0.2 keV to 120 keV for a beamline implantation. Alternatively, or in addition, implantation may be performed at an energy of 10 kV for plasma doping implantation. The implantations may use at least one of the following implant species: carbon, oxygen, fluorine, germanium, helium, argon, hydrogen, nitrogen, methane, and any combinations thereof.

In some implementations, the process 700 may, optionally, include annealing the implanted substrate prior to the oxidation, at 706. Annealing may be performed using a rapid thermal annealing process. Annealing may be performed in a temperature range of −100 to 700 degrees Celsius.

At 708, subsequent to the implantation, an oxidation of the implanted substrate may be performed to modulate oxide growth. Oxidation may include at least one of: a rapid thermal oxidation, a steam oxidation, and any combination thereof. Modulation of the oxide growth may include at least one of: suppressing oxide growth, enhancing oxide growth, and any combination thereof.

FIG. 8 illustrates a schematic diagram of a processing system 800 useful to perform processes described herein, according to some implementations of the current subject matter. One example of a beam-line ion implantation processing system is the Varian VIISTA® Trident, available from Applied Materials Inc., Santa Clara, CA. The processing system 800 may include an ion source 801 for generating ions. For example, the ion source 801 may provide an ion implant, such as the ion implant demonstrated in FIG. 8.

The processing system 800 may also include a series of beam-line components. Examples of beam-line components may include extraction electrodes 803, a magnetic mass analyzer 811, a plurality of lenses 813, and a beam parallelizer 817. The processing system 800 may also include a platen 819 for supporting a substrate 802 to be processed. The substrate 802 may be the same as the substrate 110 described above. The substrate 802 may be moved in one or more dimensions (e.g., translate, rotate, tilt, etc.) by a platform component sometimes referred to as a “roplat” (not shown). It is also contemplated that the platen 819 may be configured to perform the heated implantation processes described herein to modify one or more waveguide surfaces.

In operation, ions of the desired species, for example, dopant ions, are generated and extracted from the ion source 801. Thereafter, the extracted ions 835 travel in a beam-like state along the beam-line components and may be implanted in the substrate 802. Similar to a series of optical lenses that manipulate a light beam, the beam-line components manipulate the extracted ions 835 along the ion beam. In such a manner, the extracted ions 835 are manipulated by the beam-line components while the extracted ions 835 are directed toward the substrate 802. It is contemplated that the system 800 may provide for improved mass selection to implant desired ions while reducing the probability of undesirable ions (impurities) being implanted in the substrate 802.

In some embodiments, the processing system 800 can be controlled by a processor-based system controller such as controller 830. For example, the controller 830 may be configured to control beam-line components and processing parameters associated with beam-line ion implantation processes. The controller 830 may include a programmable central processing unit (CPU) 832 that is operable with a memory 834 and a mass storage device, an input control unit, and a display unit (not shown), such as power supplies, clocks, cache, input/output (I/O) circuits, and the like, coupled to the various components of the processing system 800 to facilitate control of the substrate processing. The controller 830 also includes hardware for monitoring substrate processing through sensors in the processing system 800, including sensors monitoring the substrate position and sensors configured to receive feedback from and control a heating apparatus coupled to the processing system 800. Other sensors that measure system parameters such as substrate temperature and the like, may also provide information to the controller 830.

To facilitate control of the processing system 800 described above, the CPU 832 may be one of any form of general-purpose computer processor that can be used in an industrial setting, such as a programmable logic controller (PLC), for controlling various chambers and sub-processors. The memory 834 is coupled to the CPU 832 and the memory 834 is non-transitory and may be one or more of readily available memory such as random-access memory (RAM), read only memory (ROM), floppy disk drive, hard disk, or any other form of digital storage, local or remote. Support circuits 836 may be coupled to the CPU 832 for supporting the processor in a conventional manner. Implantation and other processes are generally stored in the memory 834, typically as a software routine. The software routine may also be stored and/or executed by a second CPU (not shown) that is remotely located from the hardware being controlled by the CPU 832.

The memory 834 is in the form of computer-readable storage media that contains instructions, that when executed by the CPU 832, facilitates the operation of the system 800. The instructions in the memory 834 are in the form of a program product such as a program that implements the method of the present disclosure. The program code may conform to any one of a number of different programming languages.

FIG. 9 illustrates an example plasma doping processing system 900 for performing a plasma doping process, according to some implementations of the current subject matter. One example of a plasma doping processing system is the VIISta PLAD system, available from Applied Materials Inc., Santa Clara, CA.

The plasma doping processing system 900 may include a processing chamber 902, one or more ionizing coils 904, a platform and/or a pedestal 910 and an electrical connection 912 to a power source (e.g., DC bias and/or any other power source). The platform 910 may be heated and may be used for positioning of a substrate 908 for implantation. The substrate 908 may be similar to the substrate 110 and/or any other substrate, as discussed herein. The processing chamber 902 may be a vacuum chamber. The system 900 may also be coupled to a gas supply system. In some embodiments, the system 900 may also be controlled by a processor-based system controller, such as, for example, the controller 830 shown in FIG. 8.

In operation, the plasma doping processing system introduce a precursor gas into the chamber 902. An electric field, generated by applying a radio frequency (RF) or direct current (DC) voltage between the coils 904 may ionize the gas to create a plasma 906. The energetic ions and/or radicals in the plasma 906 may then interact with the substrate 908, thereby depositing thin film on the substrate 908.

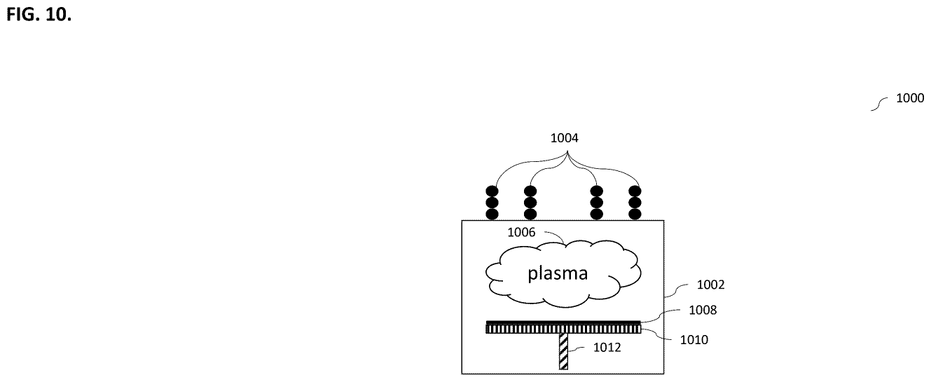

FIG. 10 illustrates an example plasma treatment processing system 1000 for performing a plasma treatment process, according to some implementations of the current subject matter. Similar to the system 900 shown in FIG. 9, the plasma treatment processing system 1000 may include a processing chamber 1002 (e.g., a vacuum chamber), one or more ionizing coils 1004, a platform and/or a pedestal 1010 and an electrical connection 1012 to a power source. The platform 1010 may likewise be heated and may be used for positioning of a substrate 1008 for plasma treatment. The substrate 1008 may be similar to the substrate(s) 102, 908, etc., as discussed herein. In some embodiments, the system 1000 may similarly be controlled by a processor-based system controller (e.g., controller 830 shown in FIG. 8). The system 1000 may operate in a similar fashion to the system 900 shown in FIG. 9 and may be used to perform a plasma process to incorporate nitrogen into silicon dioxide (SiO₂) films, thereby forming silicon oxynitride (SiON).

FIG. 11 illustrates an example oxidation processing system 1100 for performing an oxidation process, according to some implementations of the current subject matter. The oxidation may include a steam oxidation, rapid thermal oxidation, and/or any other type of oxidation. The system 1100 may be used to grow thin oxide layers on a surface of a silicon substrate 1108 that may be positioned on a platform 1110 (e.g., heated platform) in a high-temperature chamber 1102. The system 1100 may grow such oxide layers by rapidly heating the substate 1108 in an oxidizing atmosphere. In operation, the substrate 1108 is placed on the platform 1110 in a high-temperature chamber 1102 (e.g., between 800° C. and 1200° C.) and an oxidizing agent 1106 (e.g., oxygen, steam, etc.) is introduced. The oxidizing agent 1106 diffuses into the substrate 1108 and reacts with it to form silicon dioxide.

FIG. 12 illustrates an example plasma-enhanced chemical vapor deposition (PECVD) system 1200 that may be used to deposit thin films from a gas state (e.g., vapor) to a solid state on a substrate, according to some embodiments of the current subject matter. The system 1200 may be used, for example, to grow a SiN layer on top of the Si layer (e.g., during pre-implantation). The system 1200 may include a vacuum chamber, a gas delivery system, and an RF energy source. Inside the chamber, precursor gases (e.g., SiH₄ gas 1206, NH₃ gas 1210) are introduced and ionized by the radio frequency (RF) energy (e.g., using RF power source 1208) to create a plasma, which aids chemical reactions at lower temperatures. The ions and radicals generated in the plasma react with the surface of a substrate 1202 to form forming a thin film (e.g., SiN) 1204.

In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

For example, the non-transitory computer readable storage medium may include a plurality of instructions, the plurality of instructions including instructions to control components of a processing system to perform the process of patterning a semiconductor device may include providing a stack of layers atop a substrate, the stack of layers comprising a dielectric film layer, and implanting the dielectric film layer with ions. The plurality of instructions may further include instructions to control components of the processing system to perform the process of depositing a metal oxide photoresist atop the dielectric film layer and exposing and patterning the metal oxide photoresist.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element, or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

The various elements of the components as previously described with reference to FIGS. 1-8 may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an implementation is implemented using hardware elements and/or software elements may vary in accordance with any number of factors, such as desired computational rate, power levels, heat tolerances, dielectric materials used, processing cycle budget, input data rates, output data rates, memory resources, data bus speeds and other design or performance constraints, as desired for a given implementation.

One or more aspects of at least one implementation may be implemented by representative instructions stored on a machine-readable medium which represents various logic within the processor, which when read by a machine causes the machine to fabricate logic to perform the techniques described herein. Such representations, known as “IP cores”, may be stored on a tangible, machine readable medium and supplied to various customers or manufacturing facilities to load into the fabrication machines that make the logic or processor. Some implementations may be implemented, for example, using a machine-readable medium or article which may store an instruction or a set of instructions that, if executed by a machine, may cause the machine to perform a method and/or operations in accordance with the implementations. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writable or rewritable media, digital or analog media, hard disk, floppy disk, Compact Disk Read Only Memory (CD-ROM), Compact Disk Recordable (CD-R), Compact Disk Rewritable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in implementations.

At least one computer-readable storage medium may include instructions that, when executed, cause a system to perform any of the computer-implemented methods described herein.

Some implementations may be described using the expression “one implementation” or “an implementation” along with their derivatives. These terms mean that a particular feature, structure, or characteristic described in connection with the implementation is included in at least one implementation. The appearances of the phrase “in one implementation” in various places in the specification are not necessarily all referring to the same implementation. Moreover, unless otherwise noted the features described above are recognized to be usable together in any combination. Thus, any features discussed separately may be employed in combination with each other unless it is noted that the features are incompatible with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single implementation for the purpose of streamlining the disclosure. This method of disclosure is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separate implementation. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The foregoing description of example implementations has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner and may generally include any set of one or more limitations as variously disclosed or otherwise demonstrated herein.

What is claimed:

1. A method, comprising:
providing a substrate;
implanting the substrate; and
performing, subsequent to the implanting, an oxidation of the implanted substrate to modulate oxide growth.

2. The method of claim 1, wherein the substrate is a crystalline silicon.

3. The method of claim 1, wherein the substrate includes a nitride layer.

4. The method of claim 3, wherein the nitride layer is a silicon nitride layer.

5. The method of claim 1, wherein the oxidation includes at least one of: a rapid thermal oxidation, a steam oxidation, and any combination thereof.

6. The method of claim 1, further comprising, optionally, annealing the implanted substrate prior to oxidation, wherein the annealing is performed using rapid thermal annealing.

7. The method of claim 6, wherein the annealing is performed in a temperature range of 500 to 1200 degrees Celsius.

8. The method of claim 1, wherein modulating of the oxide growth includes at least one of: suppressing oxide growth, enhancing oxide growth, and any combination thereof.

9. The method of claim 1, further comprising removing one or more photoresist patterns from the substrate prior to oxidation.

10. The method of claim 1, wherein the implant is performed at an energy in a range of 0.2 keV to 120 keV for a beamline implantation.

11. The method of claim 1, wherein the implant is performed at an energy of less than or equal to 10 kV for plasma doping implantation.

12. The method of claim 1, wherein the implant is performed at a dose of 1e15 to 1e17 ions/cm², and
at a temperature of −100° to 700° Celsius for a beamline implantation, or at a temperature of 25° to 500° Celsius for plasma doping implantation.

13. The method of claim 1, wherein the implant is performed using at least one of the following implant species: carbon, oxygen, fluorine, germanium, helium, argon, hydrogen, nitrogen, methane, and any combinations thereof.

14. A method for modulating oxide growth during semiconductor manufacturing, comprising:
providing a crystalline silicon substrate;
implanting the substrate; and
performing, subsequent to the implanting, steam oxidation of the implanted substrate to modulate oxide growth.

15. The method of claim 14, further comprising, optionally, annealing the implanted substrate prior to oxidation using rapid thermal annealing.

16. The method of claim 14, wherein modulating of the oxide growth includes at least one of: suppressing oxide growth, enhancing oxide growth, and any combination thereof.

17. The method of claim 14, wherein the implant is performed using at least one of: a beamline implantation process, a plasma doping process, and any combination thereof, and using at least one of the following implant species: carbon, oxygen, fluorine, germanium, helium, argon, hydrogen, nitrogen, methane, and any combination thereof.

18. A method for modulating oxide growth during semiconductor manufacturing, comprising:
providing a substrate having a silicon nitride layer;
implanting the substrate; and
performing, subsequent to the implanting, rapid thermal oxidation of the implanted substrate to modulate oxide growth by at least one of: suppressing oxide growth, enhancing oxide growth, and any combination thereof.

19. The method of claim 18, further comprising, optionally, annealing the implanted substrate prior to oxidation using rapid thermal annealing.

20. The method of claim 18, wherein the implant is performed using at least one of: a beamline implantation process, a plasma doping process, and any combination thereof, and using at least one of the following implant species: carbon, oxygen, fluorine, germanium, helium, argon, hydrogen, nitrogen, methane, and any combination thereof.
